(19) United States
(12) Patent Application Publication
(10) Pub. No.: US 2007/0052984 A1
(43) Pub. Date: Mar. 8, 2007

(54) Apparatus and method of converting image signal for four color display device

(75) Inventors: Ho-Yong Jeong, Gyeonggi-do (KR); Cheol-Woo Park, Gyeonggi-do (KR)

Correspondence Address: H.C. PARK & ASSOCIATES, PLC, 8500 LEESBURG PIKE, SUITE 7500, VIENNA, VA, 22182, US

(73) Assignee: SAMSUNG ELECTRONICS CO., LTD., Suwon-si (KR)

(21) Appl. No.: 10/596,950

(22) PCT Filed: Jan. 6, 2005
(86) PCT No.: PCT/KR05/00030

§ 371 Date: Jun. 29, 2006

(30) Foreign Application Priority Data
Jan. 6, 2004 (KR) 10-2004-0000548

(51) Int. Cl. G03F 3/08

(52) U.S. Cl. 358/1.9; 358/518

(57) ABSTRACT

An apparatus of converting three color image signals into four color image signals having a white signal is provided, which includes: a lookup table storing a plurality of white scaling factors and a signal converter selecting a corresponding white scaling factor of the white scaling factors stored in the lookup table based on a white scaling signal from an external, converting the three color image signals into the four color image signals based on the selected white scaling factor. Like this, by converting into the four color image signals using the selected white scaling factor based on the white scaling signal from the external, the white scaling factor may be varied without change of a device in which conversion algorithm is stored, thereby manufacturing cost decreases. In addition, without usage of a white scaling factor fixed into a value, the three color image signals are converted into the four color image signals by using a white scaling factor suitable for characteristics of an LCD, thereby the operation accuracy of the LCD is improved.

### TECHNICAL FIELD

The present invention relates to an apparatus and a method of converting image signals for a four color display device.

### BACKGROUND ART

In recent, flat panel displays have been developed widely such as organic electroluminescence displays (“OLEDs”), plasma display panels (“PDPs”) and liquid crystal displays (“LCDs”) instead of heavy and large cathode ray tubes (“CRTs”).

The PDPs are devices which display characters or images using plasma generated by gas-discharge, and the OLEDs are devices which display characters or images using electric field light-emitting of specific organics or high molecules. The LCDs are devices which display desired images by applying electric field to liquid crystal layer between two panels and regulate the strength of the electric field to adjust the transmittance of light passing through the liquid crystal layer.

Although the flat panel displays usually display colors using three primary colors such as red, green and blue, recently, especially in case of LCDs, for increasing the luminance, a white pixel (or a transparent pixel) is added to the three color pixels, which is called four color flat panel displays. The four color flat panel displays display images after converting inputted three color image signals are into four color image signals.

In algorithm converting the three color image signals into the four color image signals, a white scaling factor (w) which is the ratio of a maximum luminance of a white pixel to a sum of maximum luminances of red, green, and blue pixels is used.

Luminance of the three color pixels for the red, green and blue pixels and the white pixel is generally varied based on pixel arrangements, pixel configurations, and manufacturing processes etc. of liquid crystal (LC) panel assembly and the white scaling factor also varied based on the luminance.

Since the algorithm converting the three color image signals into the four color image signals is stored in an ASIC (application specific integrated circuit) mounted on the LC panel assembly etc., the value of the white scaling factor is actually varied by variation of operation characteristics of the LC panel assembly or pixel characteristics. However, the value of the white scaling factor used in the algorithm is not changed. That is, when the value of the white scaling factor is varied, unless a new algorithm stored the varied value of the white scaling factor is stored in the ASCIC and the ASCIC is mounted on the LC panel assembly, the algorithm does not convert the three color image signals into the four color image signals by using the new white scaling factor with the varied value. In result, the four color image signal conversion is not carried by using the white scaling factor suitable for the operation characteristics of the LC panel assembly or the pixel characteristics.

### DISCLOSURE

### Technical Problem

The object of the present invention is to convert three color image signals into four color image signals by using a white scaling factor with a value corresponding to characteristics of an LC panel assembly without variation of algorithm.

The other object of the present invention is to improve image quality of a display device by converting three color image signals into four color image signals suitably to characteristics of an LC panel assembly.

### TECHNICAL SOLUTION

The object of the present invention is to convert three color image signals into four color image signals by using a white scaling factor with a value corresponding to characteristics of an LC panel assembly without variation of algorithm.

The other object of the present invention is to improve image quality of a display device by converting three color image signals into four color image signals suitably to characteristics of an LC panel assembly.

### TECHNICAL SOLUTION

An apparatus of converting three color image signals into four color image signals having a white signal is provided, which includes: a storing unit storing a plurality of white scaling factors; and a signal converting unit selecting a corresponding white scaling factor of the white scaling factors stored in the storing unit based on a white scaling signal from an external, converting the three color image signals into the four color image signals based on the selected white scaling factor and outputting the converted four color image signals.

The apparatus may further includes a digamma processing unit digamma processing the three color image signals and applying to the signal converting unit; and a gamma processing unit gamma processing the four color image signals from the signal converting unit.

The storing unit may be a lookup table.

In addition, the signal converting unit may extract a maximum value and a minimum value of the three color image signals, determine that the three image color signals are included in a fixed scaling area or a variable scaling area based on the maximum value and the minimum value, calculate a increasing ratio based on a fixed scaling factor when the three color image signals are included in the fixed scaling area, calculate the increasing ratio based on the maximum value, the minimum value, and the selected white scaling factor when the three color image signals are included in the variable scaling area, and convert the three color image signals into the four color image signals depending on the calculated increasing ratio and the three color image signals.

The fixed scaling factor may be to add “1” to the selected white scaling factor. Meanwhile, the white scaling factors may have values between 0.8 and 0.9, and each of scaling factors may have a value divided equally by eight between 0.8 and 0.9. The white scaling factors may be eight whites scaling factors.

A method of converting three color image signals into four color image signals having a white signal is provided, which includes: extracting a maximum value and a minimum value of the three color image signals; reading a white scaling signal from an external; selecting a corresponding white scaling factor of the white scaling factors based on the read white scaling signal; determining that the three image color signals are included in a fixed scaling area or a variable scaling area based on the maximum value and the minimum value; calculating a increasing ratio depending on a fixed scaling factor based on the selected white scaling factor when the three color image signals are included in the fixed scaling area; calculating the increasing ratio based on the maximum value, the minimum value, and the selected white scaling factor when the three color image signals are included in the variable scaling area; and converting the three color image signals into the four color image signals depending on the calculated increasing ratio and the three color image signals.

The method may further include: digamma processing the three color image signals; and gamma processing the converted four color image signals.

The conversion to four color image signals may include calculating first conversion image signals by multiplying the increasing ratio to the three color image signals; calculating a minimum value of the first conversion image signals; calculating a compensation value by dividing a value multiplied the selected white scaling factor to the minimum value into the scaling factor; calculating resultant three color image signals by subtracting the compensation from the first conversion image signals; and calculating the white signal by dividing the compensation into the selected white scaling factor.

### ADVANTAGEOUS EFFECTS

By the present invention, in converting the three color image signals into the four color image signals, a white scaling factor of a plurality of white scaling factors ready stored in an internal memory is selected. At this time, the selected white scaling factor has a value equal to or a value most proximate a value of a white scaling factor corresponding to characteristics of the really employed LCD. Thus, since the conversion to the four color image signals is carried by using the white scaling factor suitable for the characteristics of the LCD, the operation accuracy of the LCD is improved. In addition, since the conversion to the four color image signals is carried by using the white scaling factor suitable for the characteristics of the LCD without change of an IC stored algorithm for converting into the four color image signals, the operation accuracy of the LCD is improved without increase of manufacturing cost. Moreover, since the conversion to the four color image signals is carried by using the white scaling factor suitable for the characteristics of the LCD, image quality of the LCD increases.

### DESCRIPTION OF DRAWINGS

The present invention will become more apparent by describing embodiments thereof in detail with reference to the accompanying drawing in which:

FIG. 1 is a block diagram of an LCD according to an embodiment of the present invention;

FIG. 2 is an equivalent circuit diagram of a sub-pixel of an LCD according to an embodiment of the present invention;

FIG. 3 is a block diagram of a data processor of a signal controller according to an embodiment of the present invention;

FIG. 4 is a graph for illustrating a method for converting three color image signals into four color image signals according to an embodiment of the present invention; and

FIG. 5 is an exemplary flow chart for showing an operation of the data processor of the signal controller according to an embodiment of the present invention.

### BEST MODE

The present invention now will be described more fully hereinafter with reference to the accompanying drawings, in which preferred embodiments of the invention are shown. This invention may, however, be embodied in many different forms and should not be construed as limited to the embodiments set forth herein. Like numerals refer to like elements throughout.

In the drawings, the thickness of layers and regions are exaggerated for clarity. Like numerals refer to like elements throughout. It will be understood that when an element such as a layer, region or substrate is referred to as being “on” another element, it can be directly on the other element or intervening elements may also be present. In contrast, when an element is referred to as being “directly on” another element, there are no intervening elements present.

Then, apparatuses and methods of converting image signals for four color display devices according to embodiments of the present invention will be described with reference to the accompanying drawings.

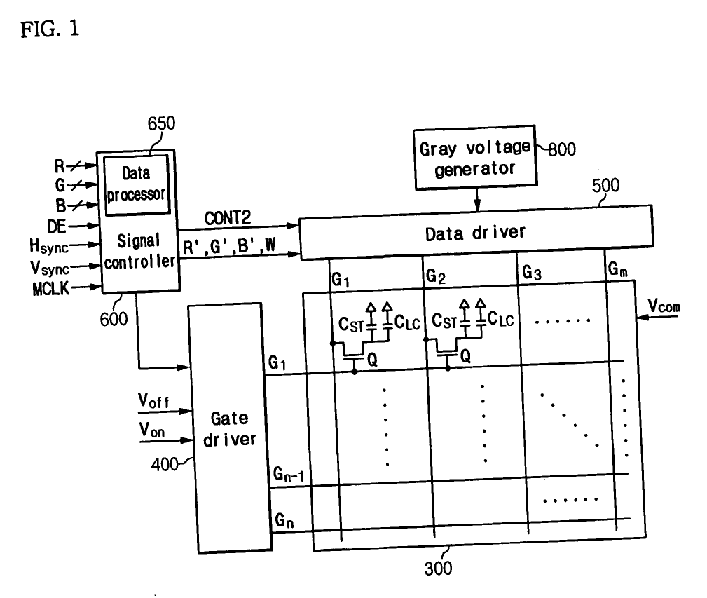

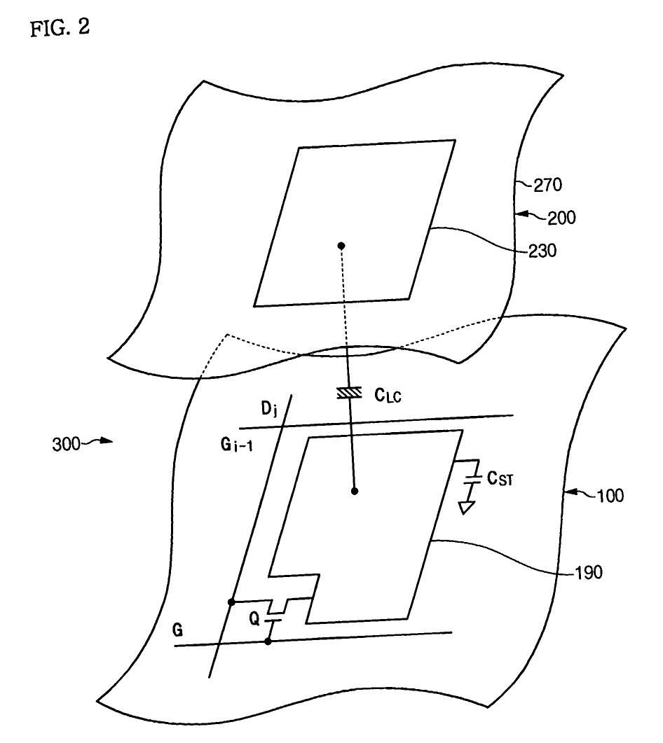

FIG. 1 is a block diagram of an LCD according to an embodiment of the present invention, and FIG. 2 is an equivalent circuit diagram of a sub-pixel of an LCD according to an embodiment of the present invention;

Referring to FIG. 1, an LCD according to an embodiment includes an LC panel assembly 300, a gate driver 400 and a data driver 500 that are connected to the LC panel assembly 300, a gray signal generator 800 connected to the data driver 500, and a signal controller 600 controlling the above elements. The signal controller 600 includes a data processor 650.

The LC panel assembly 300 includes a lower panel 100, an upper panel 200 and an LC layer 3 interposed therebetween while it includes, in a circuital view, a plurality of display signal lines G₁-Gₙ and D₁-Dₘ and a plurality of sub-pixels connected thereto and arranged substantially in a matrix.

The display signal lines G₁-Gₙ and D₁-Dₘ are provided on the lower panel 100 and include a plurality of gate lines G₁-Gₙ transmitting gate signals (also referred to as “scanning signals”), and a plurality of data lines D₁-Dₙ transmitting data signals. The gate lines G₁-Gₙ extend substantially in a row direction and they are substantially parallel to each other, while the data lines D₁-Dₘ extend substantially in a column direction and they are substantially parallel to each other.

Each pixel includes a switching element Q connected to the signal lines G₁-Gₙ and D₁-Dₘ, and an LC capacitor C_{LC} and a storage capacitor C_{ST} that are connected to the switching element Q. If unnecessary, the storage capacitor C_{ST} may be omitted.

The switching element Q is provided on the lower panel 100 and has three terminals: a control terminal connected to one of the gate lines G₁-Gₙ; an input terminal connected to one of the data lines D₁-Dₘ; and an output terminal connected to both the LC capacitor C_{LC} and the storage capacitor C_{ST}.

The LC capacitor C_{LC} includes a pixel electrode 190 provided on the lower panel 100 and a common electrode 270 provided on the upper panel 200 as two terminals. The LC layer 3 disposed between the two electrodes 190 and 270 functions as dielectric of the LC capacitor C_{LC}. The pixel electrode 190 is connected to the switching element Q, and the common electrode 270 is connected to the common voltage Vcom and covers entire surface of the upper panel 200. Unlike FIG. 2, the common electrode 270 may be provided on the lower panel 100, and both electrodes 190 and 270 may have shapes of bars or stripes.

The storage capacitor C_{ST} is an auxiliary capacitor for the LC capacitor C_{LC}. The storage capacitor C_{ST} includes the pixel electrode 190 and a separate signal line (not shown), which is provided on the lower panel 100, overlaps the pixel electrode 190 via an insulator, and is supplied with a predetermined voltage such as the common voltage Vcom. Alternatively, the storage capacitor C_{ST} includes the pixel electrode 190 and an adjacent gate line called a previous gate line, which overlaps the pixel electrode 190 via an insulator.

For color display, each pixel can represent its own color by providing one of a plurality of red, green, blue color filters and transparent filters 230 in an area corresponding to the pixel electrode 190. The color filter 230 shown in FIG. 2 is provided on the upper panel 200. However, the color filters 230 may be disposed on or under the pixel electrode 190 of the lower panel 100.

A polarizer or polarizers (not shown) are attached to at least one of the panels 100 and 200.

The gray voltage generator 800 generates two sets of a plurality of gray voltages related to the transmittance of the pixels. The gray voltages in one set have a positive polarity with respect to the common voltage Vcom, while those in the other set have a negative polarity with respect to the common voltage Vcom. The gate driver 400 is connected to the gate lines G₁-Gₙ of the panel assembly 300 and synthesizes the gate-on voltage Von and the gate off voltage Voff from an external device to generate gate signals for application to the gate lines G₁-Gₙ.

The data driver 500 is connected to the data lines D₁-Dₘ of the panel assembly 300 and applies data voltages, selected from the gray voltages supplied from the gray voltage generator 800, to the data lines D₁-Dₘ and is a plurality of integrated circuits (ICs).

The signal controller 600 controls the drivers 400 and 500, etc. and includes the data processor 610.

Now, the operation of the LCD will be described in detail.

The signal controller 600 is supplied with three color input image signals R, G and B of red, green and blue colors and input control signals controlling the display thereof such as a vertical synchronization signal Vsync, a horizontal synchronization signal Hsync, a main clock MCLK, and a data enable signal DE, from an external graphics controller (not shown). After generating gate control signals CONT1 and data control signals CONT2 and processing and modifying the three color input image signals R, G and B into four color image signals R′, G′, B′ and W′ suitable for the operation of the panel assembly 300 on the basis of the input control signals and the input image signals R, G and B, the signal controller 600 provides the gate control signals CONT1 for the gate driver 400, and the processed and modified image signals R′, G′, B′, and W′ and the data control signals CONT2 for the data driver 500. Here, the data processor 610 included in the signal controller 600 functions to convert the three color input image signals R, G and B into the four color image signals R′, G′, B′ and W′ and the operation of the data processor 610 will be described in detail later.

The gate control signals CONT1 include a vertical synchronization start signal STV for indicating the output start of the gate-on pulse (gate-on voltage period), a gate clock signal CPV for controlling the output time of the gate-on voltage Vₒₙ, and an output enable signal OE for defining the duration of the voltage Vₒₙ.

The data control signals CONT2 include a horizontal synchronization start signal STH for indicating the input start of the image signals R′, G′, B′ and W′, a load signal LOAD for instructing to apply the data voltages to the data lines D₁-Dₘ, an inversion control signal RVS for reversing the polarity of the data voltages (with respect to the common voltage V_{com}), and a data dock signal HCLK.

The data driver 500 receives a packet of the image data R′, G′, B′ and W′ for a pixel row from the signal controller 600 and converts the image data R′, G′, B′ and W′ into analog data voltages selected from the gray voltages supplied from the gray voltage generator 800 in response to the data control signals CONT2 from the signal controller 600. Thereafter, the data driver 500 applies the data voltages to the data lines D₁-Dₘ.

Responsive to the gate control signals CONT1 from the signal controller 600, the gate driver 400 applies the gate-on voltage Von to the gate line G₁-Gₙ, thereby turning on the switching elements Q connected thereto. The data voltages applied to the data lines D₁-Dₘ are supplied to the sub-pixels through the activated switching elements Q.

The difference between the data voltage and the common voltage Vcom is represented as a voltage across the LC capacitor C_{LC}, i.e., a pixel voltage. The LC molecules in the LC capacitor C_{LC} have orientations depending on the magnitude of the pixel voltage, and the molecular orientations determine the polarization of light passing through the LC layer 3. The polarizer(s) converts the light polarization into the light transmittance.

By repeating this procedure by a unit of the horizontal period (which is indicated by 1H and equal to one period of the horizontal synchronization signal Hsync, the data enable signal DE, and the gate clock signal CPV), all gate lines G₁-Gₙ are sequentially supplied with the gate-on voltage Von during a frame, thereby applying the data voltages to all pixels. When the next frame starts after finishing one frame, the inversion control signal RVS applied to the data driver 500 is controlled such that the polarity of the data voltages is reversed (which is called “frame inversion”). The inversion control signal RVS may be also controlled such that the polarity of the data voltages flowing in a data line in one frame are reversed (e.g., column inversion), or the polarity of the data voltages applied to a pixel row are reversed (e.g., dot inversion).

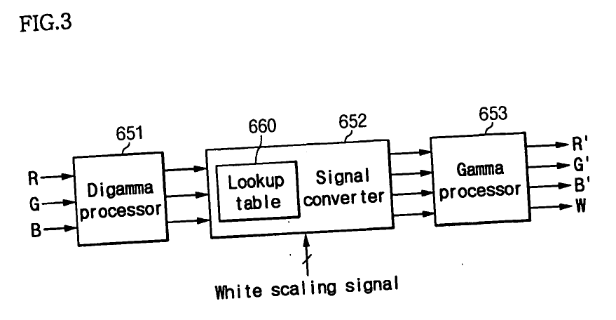

Next, an image signal conversion method of the LCD according to embodiments of the present invention will be described in detail in reference with the FIGS. 3 to 5.

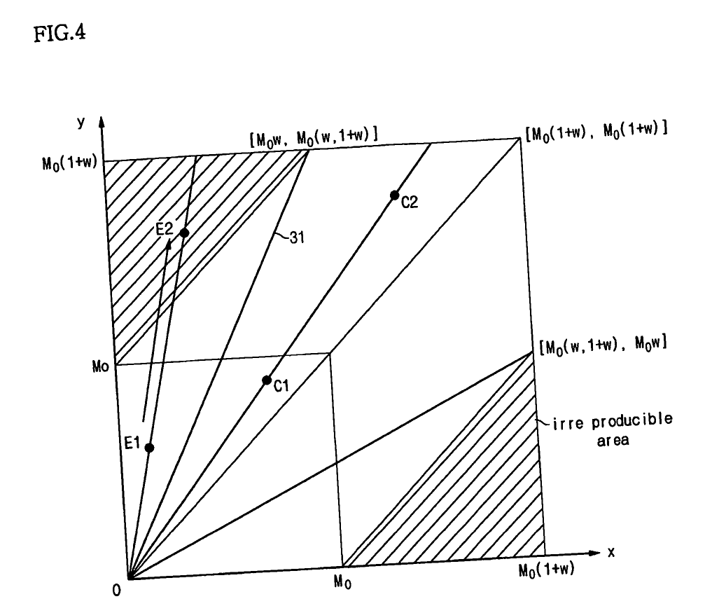

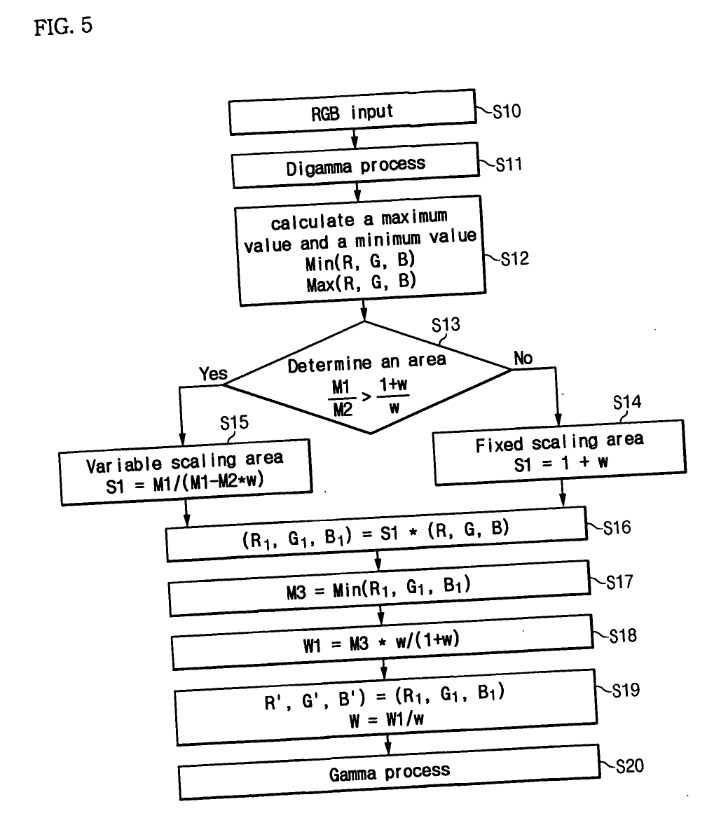

FIG. 3 is a block diagram of a conversion apparatus of the image signals that is, the data process shown in FIG. 1, according to the embodiment of the present invention. FIG. 4 is a graph for explaining a method for converting the three color image signals into the four color image signals according to the embodiment of the present invention; and FIG. 5 is a flow chart of the data processor 650 shown in FIG. 3 according to the embodiment of the present invention.

Referring to FIG. 3, the data processor 650 includes a digamma processor 651, signal converter 652 connected to the digamma processor 651, and a gamma processor 653 connected to the signal converter 652 and the data driver 500.

The predetermined number of white scaling factors w is already stored in a storage device such as a lookup table 660 or a memory in the signal converter 652 according to the present invention. The number or range of the white scaling factor w stored in the signal converter 652 is defined in consideration of storage capacity, the number of bit of signals, construction or arrangement of pixels, or characteristics of manufacturing processes. An example stored in the signal converter 652 according to the embodiment of the present invention is illustrated in [Table 1].

TABLE 1

| Value of the white scaling factor | Value of input signals |
|---|---|
| 0.8 | 000 |
| 0.814 | 001 |
| 0.828 | 010 |
| 0.842 | 011 |
| 0.857 | 100 |
| 0.871 | 101 |
| 0.885 | 110 |
| 0.9 | 111 |

As shown in [Table 1], the range of the value of the white scaling factor w is, for example, between 0.8 and 0.9, and white scaling factors w that are divided equally into eight therebetween are already stored in the lookup table 660 of the signal converter 652.

A user calculates total luminance when luminance of the three color pixels arranged on the LC panel assembly 300 is the maximum, respectively and total luminance of the white pixel by the three color image signals R, G and B applied from the external and calculates the white scaling factor w with respect to the LC panel assembly 300 actually employed. That is, the white scaling factor w=(the maximum luminance of the white pixel)/(the maximum luminance of the RGB pixels). When the calculated white scaling factor w coincides with one of the stored white scaling factors w in the lookup table 660, the user outputs a signal corresponding to the coincided white scaling factor as a white scaling signal to the signal converter 652. However, when the calculated white scaling factor w does not coincide with one of the stored white scaling factors w in the lookup table 660, the user outputs a signal corresponding to a white scaling factor with a value most approximate to a value of the calculated white scaling factor w a white scaling signal to the signal converter 652. For example, when a value of the calculated white scaling factor is 0.812 that is not the [table 1], “001” corresponding to 0.814, approximate value of the 0.812, is applied to the signal converter 652 as a white scaling signal. In the embodiment of the present invention, the white scaling signal is 3 bits, but the number of the white scaling signal may be varied not limited in the numerical value and the number of the white scaling factor stored in the lookup table 660 may also varied. After the value of the white scaling factor w corresponding to the characteristic of the LC panel assembly 300 actually employed or an approximate value thereto is applied to the signal converter 650 of the signal controller 600, the signal controller 600 converts the three color image signals R, G and B into the four color image signals R′, G′, B′ and W′.

A basic principle of converting the three color image signals R, G and B into the four color image signals R′, G′, B′ and W′ according to an embodiment of the present invention will be described in detail with reference to FIG. 4.

In a graph of FIG. 4 of which the horizontal axis and the vertical axis represent luminance, a set of input image signals including a red input signal R, a green input signal G, and a blue input signal B and let Min (R, G, B) and Max (R, G, B) be normalized luminances represented by the image signals having the lowest gray and the highest gray (referred to as “minimum image signal,” and “minimum image signal” respectively, hereinafter), respectively and variation value of them are indicated. For descriptive convenience, the minimum image signal, the minimum image signal, and the luminance, the gray are used to indicate the same meaning, the (R, G, B) may be omitted.

Any set of three color input image signals is represented as a point in a square area having vertices (0, 0), (Mo, 0), (Mo, 1), and (0, Mo) (referred to as “three color space” hereinafter). Assuming that the ratio of a maximum luminance of a white pixel to a sum of maximum luminances of red, green, and blue pixels is equal to w, the sum of the maximum luminances of the red, green, blue, and white pixels is equal to (1+w). The conversion principle is based on this fact. A primary rule is that a point C1 representing a set of three color image signals is mapped into a point C2 disposed in a straight line connecting the point C1 and the origin (0, 0) and having a distance from the origin (0, 0) (1+w) times a distance of the point C1 from the origin (0, 0). Accordingly, a point (Min (R, G, B), Max (R, G, B)) is mapped into a point ((1+w) Min (R, G, B), (1+w) Max (R, G, B)), and in this case, the multiplier (1+w) is referred to as a scaling factor. However, the luminance for a pure color such as red, green and blue cannot be increased by the addition of the white pixel, and an increment of the luminance is lower as the color is closer to a pure color. For example, as shown in FIG. 4, a point E1 representing a set of three color image signals is mapped into a point E2 if the above-described primary rule is applied thereto as it is. However, the point E2 represents a color that cannot be displayed by the four color display.

Regulating this, colors represented by the points in a hexagonal area having vertices (0, 0), (Mo, 0), [Mo(1+w), Mo*w], [Mo(1+w), Mo(1+w)], (Mo*w, Mo(1+w)], and (0, Mo) can be displayed by a four color display, while colors represented by the points in a hatched triangular area having vertices (Mo, 0), (Mo(1+w), 01, [Mo(1+w), and M*w] and a triangular area having vertices (0, Mo), [0, Mo(1+w)], and [Mo*w, Mo(1+w)] cannot be displayed by the four color display. Hereinafter, the hexagonal area defined by (0, 0), (Mo, 0), [Mo(1+w), Mo*w], [Mo(1+w), Mo(1+w)], (Mo*w, Mo(1+w)], and (0, Mo) is referred to as “reproducible area” and the hatched triangular area defined by the points (Mo, 0), [Mo(1+w), 0], [Mo(1+w), and M*w] and the hatched triangular area defined by the points (0, Mo), [0, Mo(1+w)], and [Mo*w, Mo(1+w)] are referred to as “irreproducible area.”

Therefore, points mapped into those in the irreproducible area are subjected to a secondary mapping that maps the points in the irreproducible area into the reproducible area.

First, it is noted that the points representing any set of input image signals and their mapping points are always located at on or over a line y=x shown in FIG. 4 since the horizontal axis represents the minimum image signal and the vertical axis represents the maximum image signal.

The increasing mapping of any points under a line 31 connecting the origin (0, 0) and the point [(Mo*w, Mo(1+w)] yields a point located in the reproducible area. Therefore, the points in such an area are subjected to only a primary mapping with the above-described scaling factor of (1+w), and this area is called a fixed scaling area. The line 31 is expressed as y=[(1+w)/w]x, and thus, the points (x, y) in the fixed scaling area meets y<(1+w)x/w.
(1+w)/w<Max/Min (1)

On the contrary, points satisfying (1+w)/w>Max/Min are increasingly mapped into points in the reproducible area or the irreproducible area. In detail, if a point is increasingly mapped into (1+w) increasingly mapped points disposed under a straight line y=x+Mo, which is a boundary line between the reproducible area and the irreproducible area, that is,
(1+w)(Min−Max)<1, (2)
If the (2) condition is met, the increasingly mapped points are located in the reproducible area, and, otherwise, if the (2) condition is not meet, the increasingly mapped points are located in the irreproducible area.

Accordingly, a resultant mapping of the points satisfying (1+w)/w>Max/Min is determined to have a scaling factor smaller than (1+w) and depending on the input image signals. Thus, this area is referred to as a variable scaling area.

Accordingly, the conversion from the three color image signals R, G and B the four color image signals R′, G′, B′ and W′ is defined by determining an area in which the three color image signals R, G and B is included.

Next, based on the basic principle, the conversion operation to the four color image signals will be described in detail with reference to FIG. 5.

The three color image signals R, G and B are supplied to the digamma processor 651) of the data processor 650 of the signal controller 600 (S19) and digamma converted (S11).

The image signals R, G and B from the external have a gamma curve that luminance with respect to each gray nonlinearly increases. Thus, for conversion to the four color image signals, the image signals R, G and B are converted, thereby the luminance with respect to each gray linearly increases. Accordingly, the digamma processor 651 digamma converts the three image signals R, G and B by adding a gamma function of luminance for each gray of the image signals R, G and B to an inverse function of the gamma function, and applies the digamma converted three image signals to the signal converter 652.

The signal converter 652 selects the maximum value (Max) and the minimum value (Min) by comparing magnitude (or gray) of the digamma converted three image signals and defines the maximum value (Max) as M1 and the minimum value (Min) as M2, respectively (S12). Next, the signal converter 652 determines that the digamma converted three image signals are included in the fixed scaling area or the variable scaling area (S13). At this time, based on Equation (2), when the digamma converted image signals meet (1+w)/w<M1/M2, the signal converter 652 determines that the digamma converted image signals are included in the fixed scaling area. Otherwise when the digamma converted image signals do not meet (1+w)/w<M1/M2, the signal converter 652 determines the digamma converted image signals are included in the variable scaling area.

At this time, for determining a value of the white scaling factor w used in Equation (2), the signal converter 652 reads a value of white scaling factor applied from the external and having a predetermined bit, for example 3 bits and searches a value of white scaling factor corresponding to the read value in the lookup table 660. In result, the value of white scaling factor is defined by a white scaling signal from the external.

When the three image color signals R, G and B are included in the fixed scaling area, the signal converter 652 defines the scaling factor, i.e., (1+w) as increasing ratio S1 (S14). However, when the three image color signals R, G and B are included in the variable scaling area, the signal converter 652 defines a value calculated by M1/[(M1−M2)*w] as the increasing ratio S1. Here, the increasing ratio S1 is a variable for increasingly mapping.

Next, the signal converter 652 multiplies the calculated increasing ratio S1 to the gamma converted three color image signals R, G and B and calculates the first converted three color image signals R1, G1 and B1. The signal converter 652 calculates a minimum value M3 of the three color image signals R1, G1 and B1 (S17) and calculates a compensation value W1 for obtaining resultant four color image signals R′, G′, B′ and W′ by using Equation (3) below (S18).
W1=(M3*w)/(1+w) (3)

Successively, the signal converter 652 calculates the resultant four color image signals R, G′, B′ and W′ by using Equation (4) adopted the compensation value W1 and applies it to the gamma processor 653.
(R′,G′,B′)=(R1,G1,B1)−W1
W=W1/w (4)

The gamma processor 653 gamma converts the resultant four color image signals R, G′, B′ and W′. Thus, luminance variation with respect to each gray of the gamma converted four color image signals R′, G′, B′ and W′ has the gamma curve suitable for the operation characteristics of the LCD.

Although preferred embodiments of the present invention have been described in detail hereinabove, it should be clearly understood that many variations and/or modifications of the basic inventive concepts herein taught which may appear to those skilled in the present art will still fall within the spirit and scope of the present invention, as defined in the appended claims.

1. An apparatus of converting three color image signals into four color image signals having a white signal, the apparatus comprising:
a storing unit storing a plurality of white scaling factors; and
a signal converting unit selecting a corresponding white scaling factor of the white scaling factors stored in the storing unit based on a white scaling signal from an external, converting the three color image signals into the four color image signals based on the selected white scaling factor and outputting the converted four color image signals.

2. The apparatus of claim 1, further comprising:
a digamma processing unit digamma processing the three color image signals and applying to the signal converting unit; and
a gamma processing unit gamma processing the four color image signals from the signal converting unit.

3. The apparatus of claim 2, wherein the storing unit is a lookup table.

4. The apparatus of claim 3, wherein the signal converting unit extracts a maximum value and a minimum value of the three color image signals, determines that the three image color signals are included in a fixed scaling area or a variable scaling area based on the maximum value and the minimum value, calculates a increasing ratio based on a fixed scaling factor when the three color image signals are included in the fixed scaling area, calculates the increasing ratio based on the maximum value, the minimum value, and the selected white scaling factor when the three color image signals are included in the variable scaling area, and converts the three color image signals into the four color image signals depending on the calculated increasing ratio and the three color image signals.

5. The apparatus of claim 4, wherein the fixed scaling factor is to add “1” to the selected white scaling factor.

6. The apparatus of claim 5, wherein the white scaling factors have values between 0.8 and 0.9, and each of scaling factors has a value divided equally by eight between 0.8 and 0.9.

7. The apparatus of claim 6, wherein the white scaling factors are eight whites scaling factors.

8. A method of converting three color image signals into four color image signals having a white signal, the method comprising:
extracting a maximum value and a minimum value of the three color image signals;
reading a white scaling signal from an external;
selecting a corresponding white scaling factor of the white scaling factors based on the read white scaling signal;
determining that the three image color signals are included in a fixed scaling area or a variable scaling area based on the maximum value and the minimum value;
calculating a increasing ratio depending on a fixed scaling factor based on the selected white scaling factor when the three color image signals are included in the fixed scaling area;
calculating the increasing ratio based on the maximum value, the minimum value, and the selected white scaling factor when the three color image signals are included in the variable scaling area; and
converting the three color image signals into the four color image signals depending on the calculated increasing ratio and the three color image signals.

9. The method of claim 8, further comprising:
digamma processing the three color image signals; and
gamma processing the converted four color image signals.

10. The method of claim 9, wherein the conversion to four color image signals comprises:
calculating first conversion image signals by multiplying the increasing ratio to the three color image signals;
calculating a minimum value of the first conversion image signals;
calculating a compensation value by dividing a value multiplied the selected white scaling factor to the minimum value into the scaling factor; and
calculating resultant three color image signals by subtracting the compensation from the first conversion image signals, and calculating the white signal by dividing the compensation into the selected white scaling factor.

11. A display device comprising:
a plurality of pixels arranged in a matrix;
a gray voltage generating unit generating a plurality of gray voltages;
an image converting unit converting three color image signals into four color image signals; and
a data driving unit selecting gray voltages corresponding to the converted four color signals among the gray voltages from the gray voltage generating unit,
wherein the image converting unit further comprises a storing unit storing the white scaling factors,
wherein the image converting unit selects a corresponding white scaling factor of the white scaling factors based on a white scaling signal from an external and converts the three color image signals into the four color image signals based on the selected white scaling factor.

12. The device of claim 11, wherein the signal converting unit extracts a maximum value and a minimum value of the three color image signals, determines that the three image color signals are included in a fixed scaling area or a variable scaling area based on the maximum value and the minimum value, calculates a increasing ratio based on a fixed scaling factor when the three color image signals are included in the fixed scaling area, calculates the increasing ratio based on the maximum value, the minimum value, and the selected white scaling factor when the three color image signals are included in the variable scaling area, and converts the three color image signals into the four color image signals depending on the calculated increasing ratio and the three color image signals.

13. The device of claim 12, wherein the fixed scaling factor is to add “1” to the selected white scaling factor.
